(19) United States
(12) Patent Application Publication
(10) Pub. No.: US 2012/0136476 A1
(43) Pub. Date: May 31, 2012

(54) DAMAGED SUBSTRATE HANDLING APPARATUS AND METHOD FOR SUBSTRATE PROCESSING SYSTEMS

(75) Inventors: Andrea Baccini, Mignagola Di Carbonera (IT); Marco Galiazzo, Padova (IT)

(73) Assignee: APPLIED MATERIALS, INC., Santa Clara, CA (US)

(21) Appl. No.: 13/382,992

(22) PCT Filed: Oct. 7, 2009
(86) PCT No.: PCT/EP2009/063031

§ 371 Date: Jan. 24, 2012

(30) Foreign Application Priority Data
Jul. 8, 2009 (IT) UD2009A000131

(51) Int. Cl. H01L 21/687; G06F 17/00

(52) U.S. Cl. 700/213; 414/222.01; 414/800

(57) ABSTRACT

Embodiments of the invention generally provide apparatus and methods of handling a damaged substrate in substrate processing systems, such as screen printing systems for solar cell devices. The damaged substrate handling apparatus includes a container mounted centrally on a rotary actuator assembly. A plurality of substrate supports are arranged around the periphery of the rotary actuator assembly. Damaged substrates are transferred to the container from the substrate supports. Both automated and manual apparatus and methods are disclosed.

### BACKGROUND OF THE INVENTION

1. Field of the Invention

Embodiments of the present invention generally relate to a system and method for handling damaged substrates in a substrate processing system, such as a screen printing system.

2. Description of the Related Art

Solar cells are photovoltaic (PV) devices that convert sunlight directly into electrical power. Solar cells typically have one or more p-n junctions. Each p-n junction comprises two different regions within a semiconductor material where one side is denoted as the p-type region and the other as the n-type region. When the p-n junction of a solar cell is exposed to sunlight (consisting of energy from photons), the sunlight is directly converted to electricity through the PV effect. Solar cells generate a specific amount of electric power and are tiled into modules sized to deliver the desired amount of system power. Solar modules are joined into panels with specific frames and connectors. Solar cells are commonly formed on silicon substrates, which may be single or multicrystalline silicon substrates. A typical solar cell includes a silicon wafer, substrate, or sheet typically less than about 0.3 mm thick with a thin layer of n-type silicon on top of a p-type region formed on the substrate.

The PV market has experienced growth at annual rates exceeding 30% for the last ten years. Some articles suggest that solar cell power production world-wide may exceed 10 GWp in the near future. It is estimated that more than 95% of all solar modules are silicon wafer based. The high market growth rate in combination with the need to substantially reduce solar electricity costs has resulted in a number of serious challenges for inexpensively forming high quality solar cells. Therefore, one major component in making commercially viable solar cells lies in reducing the manufacturing costs required to form the solar cells by improving the device yield and increasing the substrate throughput.

Screen printing has long been used in printing designs on objects, such as cloth or ceramics, and is used in the electronics industry for printing electrical component designs, such as electrical contacts or interconnects on the surface of a substrate. State of the art solar cell fabrication processes also use automated screen printing processes. Due to the fragile nature of the often very thin solar substrates, such as about 3 micrometers (μm) thick, cracked or broken substrates can be a common occurrence during even normal solar cell processing. Therefore, it is desirable to minimize the amount of movement and/or handoffs that are required once a cracked or broken substrate has been found. If proper care is not taken, the cracked or broken substrates can also damage the processing hardware and generate particles that can affect the device yield of the solar cell production line. Moreover, the disposal of broken or otherwise damaged silicon wafers (substrates) in the screen printing process and other substrate processes can be time consuming and require manual intervention that can decrease the substrate throughput.

Therefore, there is a need for a substrate processing system for the production of solar cells, electronic circuits, or other useful devices that has an improved method of handling damaged substrates within the system, has increased substrate throughput and a lower cost of ownership than other known systems.

### SUMMARY OF THE INVENTION

The present invention may generally provide a substrate processing system. The substrate processing system having a rotary actuator assembly with at least one substrate support disposed thereon, the rotary actuator assembly configured to move the at least one substrate support between a plurality of positions, a substrate processing chamber, the substrate processing chamber positioned to perform a process on the substrates when the at least one substrate support is in a first position of the plurality of positions and a damaged substrate handling apparatus. The damaged substrate handling apparatus has a container disposed on the rotary actuator assembly and configured to receive potentially damaged substrates from the at least one substrate support.

Embodiments of the invention may further provide a damaged substrate handling apparatus for a substrate processing system. The system including a rotary actuator assembly having at least one substrate support disposed thereon, the rotary actuator assembly configured to move the at least one substrate support between a plurality of positions and a substrate processing chamber, the substrate processing chamber positioned to perform a process on the substrates when the at least one substrate support is in a first position of the plurality of positions. The damaged substrate handling apparatus includes a container disposed on the rotary actuator assembly and configured to receive potentially damaged substrates from the at least one substrate support.

Embodiments of the invention may further provide a damaged substrate handling method for a substrate processing system. The system includes a rotary actuator assembly having at least one substrate support disposed thereon, the rotary actuator assembly configured to move the at least one substrate support between a plurality of positions, and a substrate processing chamber, the substrate processing chamber positioned to perform a process on the substrates when the at least one substrate support is in a first position of the plurality of positions. The method includes providing a damaged substrate handling apparatus that comprises a container disposed on the rotary actuator assembly, identifying a potentially damaged substrate on one of the at least one substrate supports, aligning the container with the one of the at least one substrate supports and transferring the potentially damaged substrate from the one of the at least one substrate supports to the container.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic isometric view of a system that may be used in conjunction with embodiments of the present invention to handle damaged substrates on a rotary actuator assembly.

FIG. 1B is a schematic top plan view of the system in FIG. 1A.

FIG. 2 is a partial schematic isometric view of one embodiment of the rotary actuator assembly of FIG. 1, showing the damaged substrate handling apparatus in position to receive a damaged substrate.

FIG. 3 is a plan view of one embodiment of the damaged substrate handling apparatus of FIG. 2.

FIG. 4 is a side view of the damaged substrate handling apparatus of FIG. 3.

FIG. 5 is a flow chart of a method of handling damaged substrates in a substrate processing system, according to embodiments of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the present invention provide an apparatus and method for processing damaged substrates in an automated substrate processing system, such as a screen printing system. The improved damaged substrate handling system and method will improve device yield and cost-of-ownership (CoO) of a substrate processing line. In one embodiment, the screen printing system, hereafter system, is adapted to perform a screen printing process within a portion of a crystalline silicon solar cell production line in which a substrate is patterned with a desired material and is then processed in one or more subsequent processing chambers. The subsequent processing chambers may be adapted to perform one or more bake steps and one or more cleaning steps. In one embodiment, the system is a module positioned within the Softline™ tool available from Baccini S.p.A., which is owned by Applied Materials, Inc. of Santa Clara, Calif. While the discussion below primarily discusses the system as a screen printing system capable of screen printing a pattern, such as an interconnect or contact structure, on a surface of a solar cell device, this configuration is not intended to be limiting as to the scope of the invention described herein.

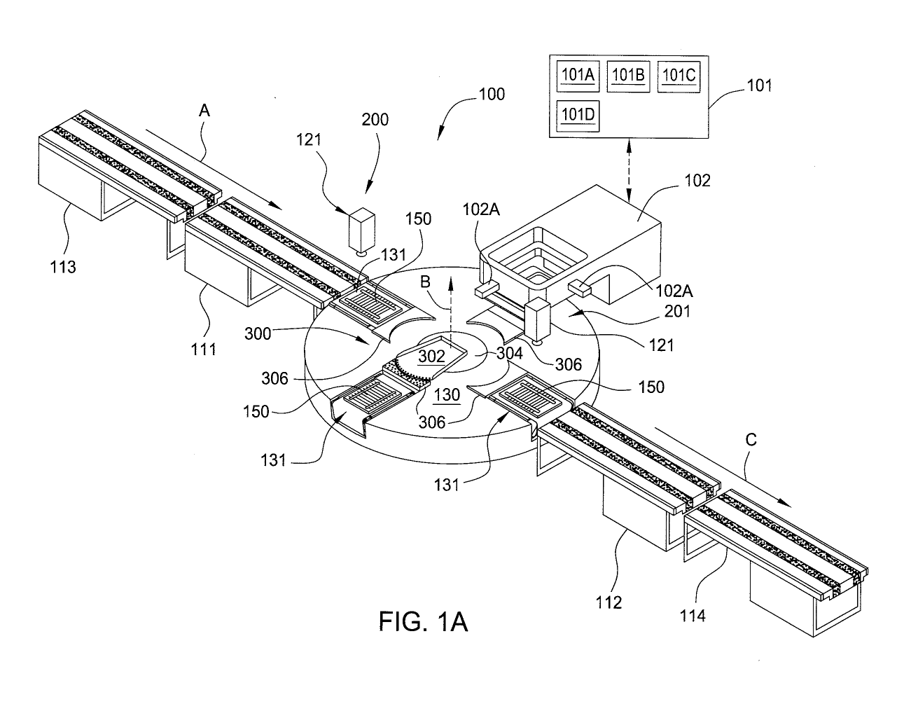

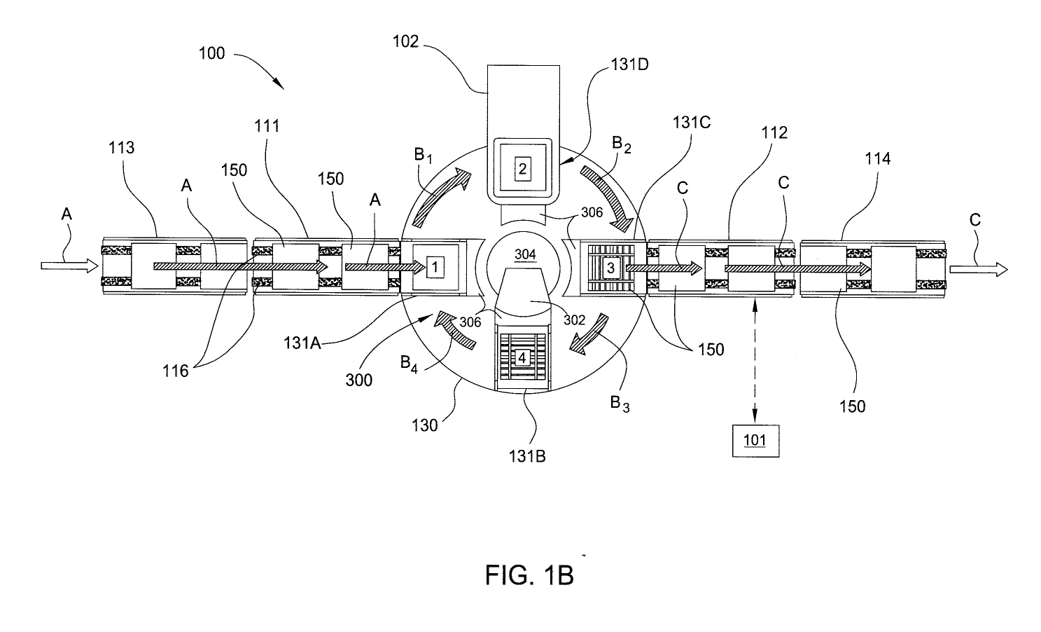

FIG. 1A is a schematic isometric view and FIG. 1B is a schematic plan view illustrating one embodiment of a screen printing system, or substrate processing system 100, that may be used in conjunction with embodiments of the present invention to handle damaged substrates. In one embodiment, the system 100 comprises an incoming conveyor 111, a rotary actuator assembly 130, a screen print chamber 102, an output conveyor 112 and a damaged substrate handling apparatus 300. The incoming conveyor 111 may be configured to receive a substrate 150 from an input device, such as an input conveyor 113, and transfer the substrate 150 to a substrate support (printing nest) 131 coupled to the rotary actuator assembly 130. The output conveyor 112 may be configured to receive a processed substrate 150 from a substrate support 131 coupled to the rotary actuator assembly 130 and transfer the substrate 150 to a substrate removal device, such as an exit conveyor 114. The input conveyor 113 and the exit conveyor 114 may be automated substrate handling devices that are part of a larger production line. For example, the input conveyor 113 and the exit conveyor 114 may be part of the Softline™ tool, of which the system 100 may be a module.

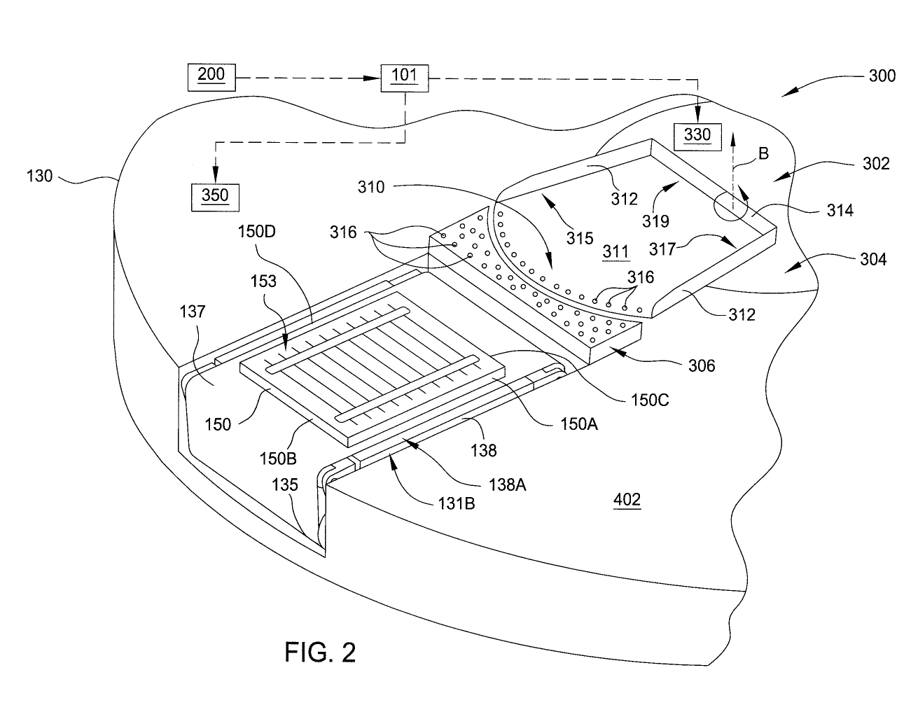

As shown in FIG. 1A, the rotary actuator assembly 130 may be rotated and angularly positioned about the “B” axis by a drive system 350, (FIG. 2), that receives control signals from a system controller 101, so that the substrate supports 131 may be selectively angularly positioned within the system 100. The rotary actuator assembly 130 may also have one or more supporting components to facilitate the control of the substrate supports 131 or other automated devices used to perform a substrate processing sequence in the system 100.

In one embodiment, the rotary actuator assembly 130 includes four substrate supports 131 that are each adapted to support a substrate 150 during the screen printing process performed within the screen printing chamber 102. While system 100 is described as a screen printing system, it should be understood that the invention may also be beneficial in other substrate processing systems, and a screen printing system is used here as one example of a substrate processing system. FIG. 1B schematically illustrates the position of the rotary actuator assembly 130 in which one substrate support 131A is in position “1” to receive a substrate 150 from the incoming conveyor 111, another substrate support 131B is in position “2” within the screen printing chamber 102 so that a second substrate 150 can receive a screen printed pattern on a surface thereof, another substrate support 131C is in position “3” for transferring a processed substrate 150 to the output conveyor 112, and another substrate support 131D is in position “4”, which is an intermediate stage between position “1” and position “3”.

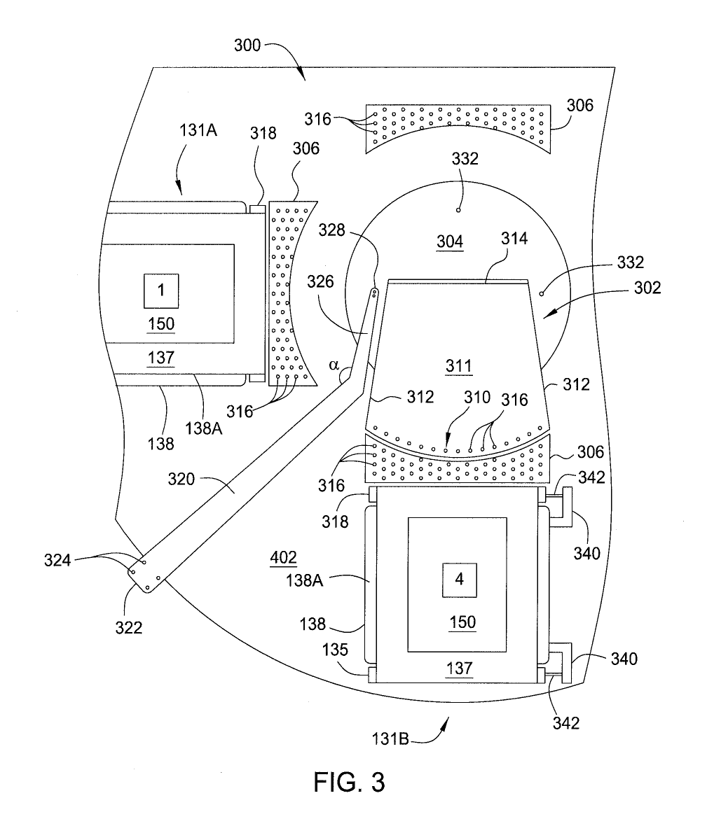

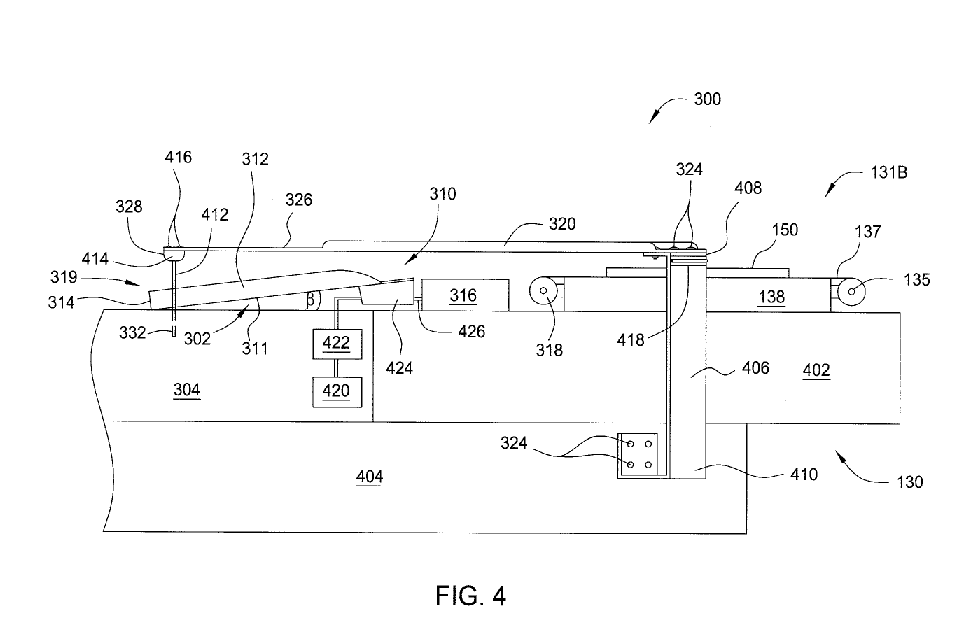

In one configuration, as illustrated in FIG. 2, each substrate support 131, (131B being illustrated in FIG. 2), generally consists of a conveyor assembly that has a feed spool 135, a take-up spool 318 (FIGS. 3 and 4), and one or more actuators 340 (FIG. 3), which are coupled to the feed spool 135 and/or take-up spool 318. The one or more actuators 340 are adapted to rotate the spools via drive shafts 342 to feed and retain a supporting material 137 positioned across a platen 138. The platen 138 generally has a substrate supporting surface 138A on which the substrate 150 and supporting material 137 are positioned during the screen printing process performed in the screen printing chamber 102. In one embodiment, the supporting material 137 is a porous material that allows a substrate 150, which is disposed on one side of the supporting material 137, to be retained on the platen 138 by a vacuum applied to the opposing side of the supporting material 137 by a conventional vacuum generating device (e.g., vacuum pump, vacuum ejector). In some embodiments, once a substrate has been processed, the spools are rotated using actuators 340 to place a clean portion of material 137 received from the feed spool 135 onto the platen 138, and to move used material from the platen 138 onto the take-up spool 318. In one embodiment, a vacuum is applied to vacuum ports (not shown) formed in the substrate supporting surface 138A of the platen 138 so that the substrate can be “chucked” to the substrate supporting surface 138A of the platen 138. In one embodiment, the supporting material 137 is a transpirable material that consists, for instance, of a transpirable paper of the type used for cigarettes or another analogous material, such as a plastic or textile material that performs the same function. An example of an exemplary printing nest (substrate support) design is further described in the co-pending U.S. patent application Ser. No. 12/257,159, filed Oct. 23, 2008 which is herein incorporated by reference.

In one embodiment, the screen printing chamber 102 in system 100 uses conventional screen printing heads available from Baccini S.p.A., which are adapted to deposit material in a desired pattern on the surface of the substrate 150 positioned on a substrate support 131 that is positioned in position “2” during the screen printing process. In one embodiment, the screen printing chamber 102 contains a plurality of actuators, for example, actuators 102A (e.g., stepper motors, servo-motors) that are in communication with the system controller 101 and are used to adjust the position and/or angular orientation of a screen printing mask to the substrate via commands sent from the system controller 101. In one embodiment, the screen printing mask is a metal sheet or plate with a plurality of features, such as holes, slots, or other apertures formed therethrough to define a pattern and placement of screen printed material (i.e., ink or paste) on a surface of a substrate 150. In one embodiment, the screen printing chamber 102 is adapted to deposit a metal containing or dielectric containing material on the solar cell substrate 150. In one embodiment, the solar cell substrate 150 has a width between about 125 mm and about 156 mm and a length between about 70 mm and about 156 mm.

In one embodiment, a damaged substrate handling apparatus 300 is mounted on the rotary actuator assembly 130, as shown in FIGS. 1A, 1B and 2. In one embodiment, the damaged substrate handling apparatus 300 includes a centrally located container 302. The container 302, in one embodiment, may be shaped similar to a “tray” that includes a base 311. Base 311 has a first end 319, a second end 310, a first side 315 and a second side 317. Two side panels 312 are attached to and extend upwards from the first side 315 and second side 317. A rear panel 314 is attached to and extends upwards from the first end 319. In some embodiments, the panels 312 and 314 form right angles with the base 311. In other embodiments, the panels 312 and 314 are slanted outward and form an angle slightly greater than 90° with the base 311. The second end 310 of the base 311 is open and is generally directed radially away from the center of the rotary actuator assembly 130. In some embodiments, the container 302 is mounted to a central portion 304 of the rotary actuator assembly 130. In one embodiment, the central portion 304 may be fixed to a stationary base 404 (FIG. 4) of the rotary actuator assembly 130. A top peripheral portion 402 of the rotary actuator assembly 130, on which the substrate supports 131A-D are disposed, is adapted to rotate on the stationary base 404 of the rotary actuator 130, about the central portion 304. The system controller 101 can be used to control the rotation of the top portion 402 using a drive system 350 (FIG. 2) so that each of the substrate supports 131A-D can be separately aligned with the open end 310 of container 302 that is aligned in a desired position within the system, such as position 4 shown in FIG. 1B. In one embodiment, drive system 350 may include a motor attached to the base 404 and includes an output shaft with a drive gear mounted thereon. The drive gear engages a driven gear on the top peripheral portion 402 to rotate the top peripheral portion 402, when the motor is activated.

Alternatively, in some embodiments, the central portion 304 may be rotatable relative to the base 404 of the rotary actuator assembly 130, such that the open end 310 of container 302 can be independently oriented relative to each of the substrate supports 131A-D, regardless of the position of the top portion 402 of the rotary actuator assembly 130. In one embodiment, a drive system 330 found in the damaged substrate handling apparatus 300 is used to controllably rotate the central portion 304, and the container 302 mounted thereon, using signals received from the system controller 101. While the container 302 is shown mounted on the rotary actuator assembly 130, it should be understood that the container 302 could be mounted on intermediate supports between the container 302 and the rotary actuator assembly 130, or other supports according to further embodiments of the invention. In the different embodiments of the mounting arrangement, container 302 is coupled to the rotary actuator assembly 130 in a manner that allows transfer of damaged substrates from one or more of the positions “1”-“4,” (or positions therebetween), of the rotary actuator assembly 130.

In one aspect of the invention, the damaged substrate handling apparatus 300 includes air bearing devices 306. The air bearing devices 306 are each mounted adjacent to and radially inward of the substrate supports 131A-D, as shown in FIGS. 1A and 1B. The air bearing devices 306 each include a plurality of ports 316 for directing air upwards, to support and allow the damaged substrates to be near frictionlessly transferred from the substrate supports 131A-D into the container 302. Compressed air is supplied to the air bearing devices 306 from a source of compressed air 420 via solenoid valve 422 (FIG. 4). In one embodiment, the compressed air is supplied via an outlet tube 426 that aligns with an input port (not shown) of the air bearing device 306, associated with the substrate support 131 that is aligned with the open end 310 of the container 302 (see FIG. 4). In one embodiment, the base 311 contains a plurality of ports 316 (FIG. 2) to allow the damaged substrates to be easily transferred into the container 302. In this embodiment, compressed air from valve 422 is also supplied to ports 316 in base 311 using a manifold 424. In other embodiments, the compressed air may be supplied to the air bearing devices using a separate solenoid valve for each air bearing device. The controller 101, in these embodiments, operates the solenoid valve associated with the substrate support 131 that is aligned with the open end 310 of the container 302. In some embodiments, the open end 310 of the container 302 is at a higher elevation than the first end 319 as can be seen in FIG. 4. In these embodiments, the base 311 of the container 302 form an angle 13 with the top of the central portion 304 (as well as the remainder of the top of the rotary actuator 130).

Further details of one embodiment of the damaged substrate handling apparatus 300 are best seen in FIGS. 3 and 4. In FIGS. 3 and 4, the container 302 is aligned with position “4,” to receive a substrate 150 from substrate support 131B. The substrate supports (e.g., reference numerals 131A, 131B in FIGS. 3 and 4) are mounted on top portion 402 of rotary actuator assembly 130. As noted above, each of the substrate supports include a feed spool 135 and a take-up spool 318, for supplying and receiving the supporting material 137, respectively. Alternatively, in some embodiments, the spools 135 and 318 and the supporting material 137 may function as a conveyor, such that the supporting material 137 is returned to the spools adjacent to the platen 138. As shown, however, clean supporting material 137 is supplied from the feed spool 135 and stored after use on the take-up spool 318. Typically, after performing one or more screen printing processes, some of the printed material is accidently deposited on the web of supporting material 137. By feeding new material onto the platen 138 before receiving a new substrate thereon, contamination of the new substrate can be avoided. The feed spool 135 and the take-up spool 318, are driven by one or more actuators 340 via drive shafts 342. In one embodiment, the drive shafts 342 may be extensions of the spools' axles, while in alternative embodiments the drive shafts 342 may be adapted to engage the axles of spools 135 and 318.

As previously described, in some embodiments of the damaged substrate handling apparatus 300, central portion 304 of the rotary actuator assembly 130, may be free to rotate with respect to the base 404. In one configuration, as the top portion 402 is rotated, friction between the top portion 402 and the central portion 304 may cause the central portion 304 to rotate with respect to the top portion 402. To maintain the position of the central portion 304, (for example, so that container 302 is aligned with position 4 as shown in the figures) an arm 320 is provided, which is attached to a stationary component, such as the base 404 of the rotary actuator 130. In one embodiment, a first end 322 of arm 320 is supported by a bracket 406 that is attached to the base 404 of the rotary actuator assembly 130. Suitable fasteners 324 (i.e., nuts and bolts) are used to attach the arm 320 to a top horizontal portion 408 of the bracket 406 and to attach the U-shaped bottom portion 410 of the bracket 406 to the base 404 of the rotary actuator assembly 130. The arm 320 extends over the rotary actuator assembly 130, and includes an end portion 326 that is attached at an angle a (FIG. 3) to the remainder of the arm 320. By attaching the end portion 326 at an angle, the arm 320 can be mounted in an intermediate position between positions “1” and “4,” and the end portion 326 does not interfere with the movement of the substrates 150 in either position. At the distal end 328 of the arm 320, suitable fasteners 416 (i.e., screws) are used to attach a pin 412, mount 414 and the arm 320 to the central portion 304. In one embodiment, the arm 320, or coupling between the arm 320 and the pin 412 is flexible, such that upwards pressure on the arm 320 or pin 412 will allow the pin 412 to be disengaged from a bore 332 formed in central portion 304, thus allowing the central portion 304 to be rotated about the base 404, so that the container 302 may align with one of the positions 1-4 on the rotary actuator assembly 130.

In other embodiments, the arm 320 may be rigid and the bracket 406 includes a hinge 418, such that the top portion 408 of the bracket 406 and the arm 320 can be pivoted vertically about the hinge 418. In this configuration, once the pin 412 is aligned with the desired bore 332, the arm 320 can be lowered such that the pin 412 engages with the bore 332, once again fixing the relative position of the central portion 304, with respect to the base 404.

Returning to FIG. 1A, in one embodiment, the system 100 includes an inspection assembly 200 adapted to inspect a substrate 150 located on the substrate support 131 in position “1”. The inspection assembly 200 may include one or more cameras 121 positioned to inspect an incoming, or unprocessed substrate 150, located on the substrate support 131 in position “1”. In one embodiment, the inspection assembly 200 includes at least one camera 121 (e.g., CCD camera) and other electronic components capable of inspecting and communicating the inspection results to the system controller 101 used to analyze the orientation and position of the substrate 150 on the substrate support 131. In one embodiment, the substrate supports 131 may each contain a lamp (not shown), or other similar optical radiation device, to illuminate a substrate 150 positioned on the substrate support 131 so that it can be more easily inspected by the inspection assembly 200.

In one embodiment, the system 100 may also include a second inspection assembly 201 that is positioned to inspect a substrate after the material is deposited on the surface of the substrate in the screen printing chamber 102 to analyze the position of the deposited layer on the substrate surface. In one configuration, the second inspection assembly 201 is similar to the inspection assembly 200, discussed above, and is generally capable of inspecting and communicating the inspection results to the system controller 101. In one example, the second inspection assembly 201 is adapted to inspect a substrate 150 located on the substrate support 131 in position “3”. The inspection assembly 201 may include one or more cameras 121 (e.g., CCD camera) positioned to inspect a processed substrate 150 located on the substrate support 131 in position

The system controller 101 facilitates the control and automation of the overall system 100 and may include a central processing unit (CPU) 101A, memory 101B, and support circuits (or I/O) 101C. The CPU 101A may be one of any form of computer processors that are used in industrial settings for controlling various chamber processes and hardware (e.g., conveyors, detectors, motors, fluid delivery hardware, etc.) and monitor the system and chamber processes (e.g., substrate position, process time, detector signal, etc.). The memory 101B is connected to the CPU 101A, and may be one or more of a readily available memory, such as random access memory (RAM), read only memory (ROM), floppy disk, hard disk, or any other form of digital storage, local or remote. Software instructions and data can be coded and stored within the memory 101B for instructing the CPU 101A. The support circuits 101C are also connected to the CPU 101A for supporting the processor in a conventional manner. The support circuits 101C may include cache, power supplies, clock circuits, input/output circuitry, subsystems, and the like. A program (or computer instructions) readable by the system controller 101 determines which tasks are performable on a substrate. Preferably, the program is software readable by the system controller 101, which includes code to generate and store at least substrate positional information, the sequence of movement of the various controlled components, substrate inspection system information, and any combination thereof.

In some embodiments, the software includes subroutines associated with the damaged substrate handling apparatus 300 that are adapted to recognize a potentially damaged substrate using optical images of the substrate received from an optical inspection assembly such as one of the inspection assemblies, such as inspection assemblies 200 or 201. When a potentially damaged substrate is identified, the system controller 101 can “tag” the substrate for disposal. By tagging the substrate, information including the location of the tagged substrate (on which specific substrate support 131A-D, the tagged substrate is disposed) is stored in the memory 101B. In some embodiments, the detection of the damaged substrate may simply be displayed. A display 101D associated with the system controller 101, may display a simple message such as “Damaged Substrate Located in Support 131C.” In this case, an operator can then manually rotate the rotary actuator assembly 130, as described below with respect to manual operation, until the substrate support is aligned so that the damaged substrate can be transferred into the container 302. Once aligned, the operator may manually activate the actuators used to turn the spools 318 and 135 (counter-clockwise as seen in FIG. 4) to cause the web of support material 137 to move and transfer the damaged substrate from the substrate support to the container 302. As the damaged substrate is transferred to the container 302, a portion of clean support material 137 from the feed spool 135 replaces the used material disposed over the platen 138, while the used material is simultaneously received by the take-up spool 318. In this manner, a required step of replacing the used material is combined with transferring the damaged substrate into container 302, which can reduce the chance of particles disposed on the used portion of the support material 137 from contaminating subsequently processed substrates. Therefore, even in manual operations, the throughput of the system 100 and device yield can be improved.

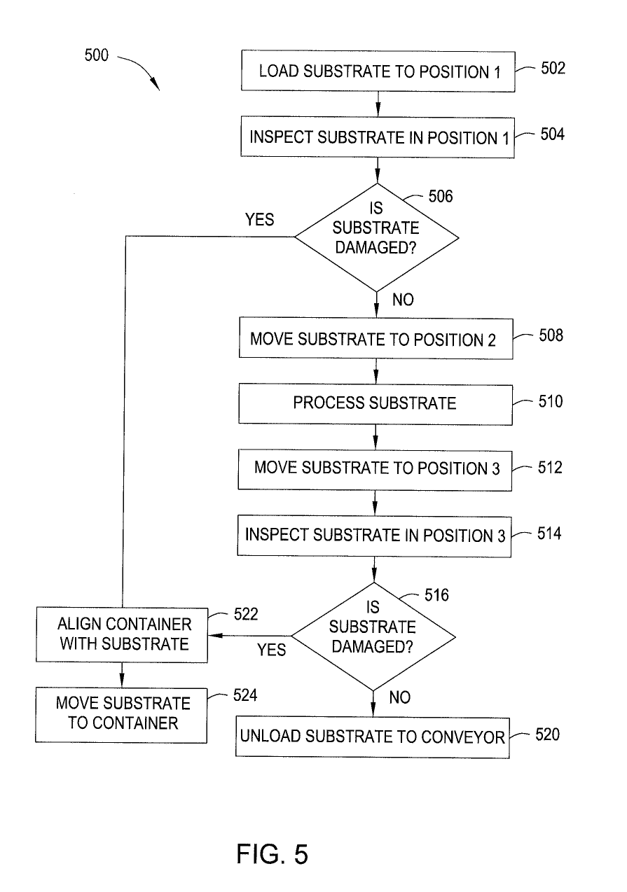

In FIG. 5, a flow chart of an operational sequence 500 illustrating the progression of a substrate through system 100 is shown. Referring to the FIGS. 1B and 5, in a substrate loading operation 502, a first substrate 150 is loaded along the path “A” from incoming conveyor 111 onto the substrate support 131A located in position “1” of the rotary actuator assembly 130. In one example, as illustrated in FIGS. 1A, 1B and 2, a supporting material 137 in the substrate support 131 is adapted to cooperatively receive the substrate 150 from the belts 116 contained in the incoming conveyor 111 using commands sent by the system controller 101.

Next, in an inspection operation 504, the optical inspection assembly 200 positioned adjacent to position “1” is used to capture an image of one or more features of the substrate 150 (e.g., edges 150A-150D illustrated in FIG. 2).

In step 506, based on the image data collected and received by the system controller 101 during step 504, the system controller 101 determines if the substrate 150 is damaged. If the substrate is not damaged, the process moves to step 508. If the substrate is damaged, the process moves to step 522 as explained below.

In operation 508, the rotary actuator assembly 130 is rotated such that the substrate support 131A containing the loaded substrate 150 is moved in a clockwise direction along a path B₁ into position “2” within the printing chamber 102.

In operation 510, a process is conducted on the substrate 150 such as depositing a pattern layer (i.e., metal or dielectric materials) on the surface of the substrate using a screen printing process. In one embodiment, a second substrate 150 is loaded onto the substrate support 131B now located in position “1”. In this embodiment, the second substrate 150 follows the same path as the first loaded substrate 150 throughout the operational sequence.

In operation 512, the rotary actuator assembly 130 is rotated such that the substrate support 131A containing the substrate 150 is moved in a clockwise direction along a path B₂ into position “3” so that the screen printed pattern (or other process results) on the substrate can be analyzed by the optical inspection assembly 201. While processes discussed in the operational sequence 500 generally disclose the use of a rotary actuator assembly 130 that has four substrate supports 131, this configuration is not intended to be limiting, since any number of substrate supporting devices that can be positioned by an automation assembly can be used without deviating from the basic scope of the invention described herein. In one embodiment, a third substrate 150 is loaded onto the substrate support 131C now located in position “1”. In this embodiment, the third substrate 150 follows the same path as the previous substrates 150 throughout the operational sequence.

Next, in a second inspection operation 514, the optical inspection assembly 201 positioned adjacent to position “3” uses camera 121 to capture one or more images of the substrate 150.

In step 516, and based on the image, the system controller 101 uses the collected data (images from camera 121) to determine if the substrate 150, or the screen printing pattern is damaged or otherwise defective. If the substrate is not damaged, the process moves to step 520. If the substrate is damaged, the process moves to step 522 as explained below.

In operation 520, the processed and inspected substrate 150 in position “3” is unloaded from the substrate support 131 to the output conveyor 112, by turning spools 318 and 135 such that the material 137 and the substrate is directed toward the output conveyor 112. The system controller 101 includes software to activate the actuators 340 used to turn the spools 318 and 135 in an opposing, or reverse direction, after the substrate is transferred to the output conveyor 112. The movement of the supporting material in reverse is continued until the used portion of material 137 that was supporting the substrate 150 is on the take-up reel 318 and clean support material is on the platen 138 so that the next substrate can be received by the clean support material 137.

When a damaged substrate is identified in either step 506 or step 516, the process proceeds to step 522. In step 522, the container 302 is aligned with the substrate support 131 on which the damaged substrate is supported. In one embodiment, this is accomplished by rotating the top portion 402 of the rotary actuator assembly 130, until the substrate support 131 with the damaged substrate is aligned with the container 302. For example, the top portion 402 of the rotary actuator assembly 130 is rotated such that the substrate support 131A containing the damaged substrate is moved in a clockwise direction along a path B₃ into position “4.” In embodiments where the central portion 304 and container 302 are rotatable with respect to base 404, the container 302 (mounted on the central portion 304) can be rotated until it aligns with the substrate support 131 containing the damaged substrate, regardless of the position (1-4) in which the substrate support 131 with the damaged substrate is located.

Once the container and the damaged substrate are aligned, the process proceeds to step 524. In step 524, the damaged substrate 150 is unloaded from the substrate support 131 to the container 302, by turning spools 318 and 135 using actuators 340 such that the support material 137 and the substrate 150 are moved towards the container 302. As previously described, as the spools are turned in this direction, new material is fed to the platen 138 from the feed spool 135 and used material is collected onto the take-up spool 318. Thus, by using the spools and support material to transfer the damaged substrate, this action is combined with replacing the material 137 on the platen 138 for the next loaded substrate. In embodiments where the damaged substrate is removed in position “4,” after removal of the damaged substrate, the top portion 402 of the rotary actuator assembly 130 is rotated such that the empty substrate support 131A is moved in a clockwise direction along a path B₄ into position “1,” to receive the next unprocessed substrate from incoming conveyor 111.

### Manual Operation

The above-described operational sequence 500 can apply to both manual and automated damaged substrate handling methods, according to embodiments of the invention. In manual embodiments, an operator responds to an indicator that a damaged substrate has been identified. In addition to the display 101D as previously described, an alarm, either audible (i.e., bell, whistle, buzzer) or visual (i.e., light, strobe, flag), or both can be used to alert the operator. The operator can then note the position of the damaged substrate as indicated on the display 101D, or visually if no display is provided. The operator prompts the system controller 101 via an input device (i.e., keyboard, mouse or control switches), to rotate either the central portion 304 and the container 302 via drive system 330, or the top portion 402 via drive system 350 to align the substrate support 131 having the damaged substrate with the container 302. The operator can then prompt the system controller 101 to activate the actuators 340 coupled to the spools 135 and 318 to transfer the damaged substrate to the container 302.

In one embodiment, the central portion 304 and the container 302 are fixed relative to the base 404. In one example, position 4 may be used as a visual inspection station, and container 302 may remain aligned with this position using the arm 320 so that it can receive the damaged substrates from the substrate support 131 oriented in position 4. By providing an apparatus and method to handle the damaged substrates on the rotary actuator assembly 130, the damaged substrates are removed from the system prior to transfer to the exit conveyer 114 and before subsequent processes are performed on the substrate. The apparatus and methods described herein can thus improve system throughput, reduce the space required for stand alone damaged substrate handling systems or receptacles, prevent the broken substrate from contaminating multiple areas of the system 100, and avoid damage to any downstream system components.

### Automated Operation

As most substrate processing systems, such as the system 100 shown in FIGS. 1A and 1B, are automated, an automated damaged substrate handling apparatus 300 and method may be desired to reduce the need for operator intervention. In one embodiment, the support circuits 101C include positional sensors (not shown) that provide information to the CPU 101A indicating the position of the container 302 (the direction the open end 310 is directed) as well as the position of the top portion 402 of the rotary actuator assembly 130. When the system controller 101 determines that a substrate is damaged, the substrate is tagged and the location of the damaged substrate (substrate support 131A-D) is stored in memory 101B. In some embodiments, the system controller 101 may initially only note the location of the damaged substrate, for example, on substrate support 131A. The system controller 101 may allow the damaged substrate to proceed to the other positions (131B-D) and simply withhold processing operations (such as screen printing in position “2”, and transfer to the output conveyor in position “3”) that would normally be performed on non-damaged substrates. The damaged substrate can remain in substrate support 131A, while subsequent substrates are loaded onto substrates supports 131B-D. When the substrate support 131A is in position “4” and aligned with the container 302, the system controller 101 activates spools 135 and 318 to transfer the damaged substrate to the container 302. The substrate support 131A is then ready to accept a new substrate when it is moved to position “1”. The non-damaged substrates on substrate supports 131B-D may continue to be processed as normal during this procedure. In alternative embodiments, when the system controller 101 determines that a substrate is damaged, it rotates the central portion 304 via drive system 330 until the open end 310 of the container 302 is aligned with the substrate support having the damaged substrate. In some embodiments the substrate support will be in position “1” or position “3,” as the substrate will have been imaged by inspection assembly 200 or 201. After aligning the open end 310 of the container 302 with the substrate support having the damaged substrate, the system controller 101 activates spools 135 and 318, via actuators 340, to transfer the damaged substrate to the container 302. This procedure allows the damaged substrate to be removed from the substrate support in any of the positions, so that the substrate support is available to accept a new substrate. This is particularly useful when the damaged substrate is in position “1”, as the rotary actuator assembly 130 may resume normal operations immediately after removal of the damaged substrate.

While the foregoing is directed to embodiments of the present invention, other and further embodiments of the invention may be devised without departing from the basic scope thereof, and the scope thereof is determined by the claims that follow.

1. A substrate processing system, comprising:
a rotary actuator assembly having at least one substrate support disposed thereon, the rotary actuator assembly configured to move the at least one substrate support between a plurality of positions;
a substrate processing chamber, the substrate processing chamber positioned to perform a process on the substrates when the at least one substrate support is in a first position of the plurality of positions; and
a damaged substrate handling apparatus, the damaged substrate handling apparatus including a container coupled to the rotary actuator assembly and configured to receive potentially damaged substrates from the at least one substrate support.

2. The substrate processing system of claim 1, wherein the container is aligned with a second position of the plurality of positions to receive potentially damaged substrates from the at least one substrate support when it is in the second position of the plurality of positions.

3. The substrate processing system of claim 1, wherein the container is mounted on a central portion of the rotary actuator assembly, the central portion and the container being rotatable relative to a base of the rotary actuator assembly, so that the container can be aligned with the at least one substrate support in any of the plurality of positions to receive potentially damaged substrates from the at least one substrate support.

4. The substrate processing system of claim 1, wherein the container comprises:
a base having first and second ends and first and second sides extending between the first and second ends, the second end having an opening which is aligned perpendicular to a radial direction which extends between a central portion of the rotary actuator assembly and a periphery of the rotary actuator assembly.

5. The substrate processing system of claim 4, wherein the container is mounted on the central portion such that the first end is at a lower elevation than the second end.

6. The substrate processing system of claim 1, wherein the at least one substrate support comprises:
a first spool;
a second spool;
a support material extending between the first and second spools, and being adapted to support a substrate; and
an actuator configured to rotate the first and second spools to transfer a potentially damaged substrate from the at least one substrate support into the container.

7. The substrate processing system of claim 6, wherein the damaged substrate handling apparatus further comprises at least one air bearing mounted on the rotary actuator assembly adjacent to and radially inward of the at least one substrate support, the at least one air bearing configured to direct air to support at least a portion of the potentially damaged substrate as it is directed from the at least one substrate support into the container.

8. The substrate processing system of claim 7, wherein:
the at least one substrate support comprises a plurality of substrate supports;
the at least one air bearing comprises a plurality of air bearings; and
the plurality of air bearings are each mounted adjacent to and radially inward of each of the plurality of substrate supports.

9. The substrate processing system of claim 1, further comprising an input conveyor positioned to load substrates onto the at least one substrate support in a second position of the plurality of positions;

10. The substrate processing system of claim 9, further comprising an output conveyor positioned to receive substrates from the at least one substrate support in a third position of the plurality of positions.

11. The substrate processing system of claim 1, further comprising:
an optical inspection assembly, the optical inspection assembly positioned to capture an optical image of a substrate; and
a system controller comprising software that is configured to recognize a potentially damaged substrate using the optical image received from the optical inspection assembly, and to store information including on which substrate support of the at least one substrate support the potentially damaged substrate is disposed.

12. The substrate processing system of claim 11, wherein:
the at least one substrate support comprises a plurality of substrate supports arranged about a periphery of the rotary actuator assembly;
the container is mounted on a central portion of the rotary actuator assembly, the central portion and the container being rotatable relative to the remainder of the rotary actuator assembly using a drive system; and
the software is further configured to prompt the system controller to send a control signal to the drive system to rotate the central portion and the container, such that container is aligned with the substrate support on which the potentially damaged substrate is disposed.

13. The substrate processing system of claim 11, wherein:
the at least one substrate support comprises a plurality of substrate supports arranged about a periphery of the rotary actuator assembly;
the system further comprises a drive system to rotate the rotary actuator to move each of the plurality of substrate supports into each of the plurality of positions; and
the software is further configured to prompt the system controller to send a control signal to the drive system to rotate the rotary actuator, such that container is aligned with the substrate support on which the potentially damaged substrate is disposed.

14. The substrate processing system of claim 1 wherein the rotary actuator assembly further comprises:
a stationary base;
a central portion having the container disposed thereon and at least one bore on a top surface thereof, the central portion being rotatably mounted on the base;
a top peripheral portion adapted to rotate on the stationary base about the central portion, the at least one substrate support being disposed on the top peripheral portion;
a bracket having a bottom portion and a top portion, the bottom portion of the bracket being attached to the stationary base;
an arm attached at a first end to the top portion of the bracket and extending over the top peripheral portion and the central portion; and
a pin mounted to a distal second end of the arm and extending downward, the pin being adapted to engage the at least one bore to prevent the central portion from rotating relative to the base.

15. A method of handling damaged substrates in a substrate processing system, comprising:
receiving a substrate on a first surface of a supporting material disposed over a supporting surface of a substrate support;
analyzing the substrate to determine if the substrate is damaged;
aligning a container and the substrate support so that a substrate can be transferred from the supporting material to the container; and
transferring the substrate from the supporting material to the container after it has been determined that the substrate is damaged.

16. The method of claim 15, wherein aligning the container and the substrate support comprises rotating a rotary actuator on which the substrate support is disposed until it is aligned with the container.

17. The method of claim 15, wherein aligning the container and the substrate support comprises positioning the container relative to the substrate support.

18. The method of claim 15, wherein receiving a substrate on the surface of the supporting material, further comprises:
receiving the substrate on a first conveyor;
transferring the substrate from the first conveyor to the first surface of the supporting material by moving the supporting material across the supporting surface of the substrate support; and
halting the moving of the supporting material across the supporting surface of the substrate support when the substrate is in a first position,
wherein the substrate is analyzed while the substrate is positioned in the first position on the substrate support.

19. The method of claim 18, further comprising:
evacuating a region behind a second surface of the supporting material to retain the substrate when it is disposed on the first surface in the first position; and
aligning the container and the substrate support further comprises rotating a rotary actuator on which the substrate support is disposed until the substrate support is aligned with the container.

20. The method of claim 15, further comprising:
positioning the substrate in a screen printing chamber after receiving the substrate on the first surface of the supporting material; and then
depositing a material on the substrate disposed on the substrate support using a screen printing process before analyzing the substrate.

21. The method of claim 15, wherein analyzing the substrate to determine if the substrate is damaged comprises:
capturing an image of at least a portion of the substrate;
analyzing the image to determine if a defect exists; and
storing information about the damaged substrate in memory of a system controller after it has been determined that the substrate is damaged.

22. The method of claim 21, wherein:
the substrate processing system comprises a plurality of substrate supports;
the information stored about the damaged substrate includes information identifying on which substrate support of the plurality of substrate supports the damaged substrate is disposed; and
aligning the container and the substrate support comprises rotating a rotary actuator on which the plurality of substrate supports is disposed until the substrate support on which the damaged substrate is disposed is aligned with the container.

23. The method of claim 21, wherein:
the substrate processing system comprises a plurality of substrate supports;
the information stored about the damaged substrate includes information identifying on which substrate support of the plurality of substrate supports the damaged substrate is disposed; and
aligning the container and the substrate support comprises positioning the container until the container is aligned with the substrate support on which the damaged substrate is disposed.
